(19) United States
(12) Patent Application Publication
(10) Pub. No.: US 2007/0090372 A1
(43) Pub. Date: Apr. 26, 2007

(54) LIGHT EMITTING DIODE

(75) Inventors: Liang-Wen Wu, Tao-Yung Hsien (TW); Fen-Ren Chien, Tao-Yung Hsien (TW)

Correspondence Address: J C PATENTS, INC., 4 VENTURE, SUITE 250, IRVINE, CA, 92618, US

(73) Assignee: FORMOSA EPITAXY INCORPORATION, Tao-Yung Hsien (TW)

(21) Appl. No.: 11/536,425

(22) Filed: Sep. 28, 2006

(30) Foreign Application Priority Data
Oct. 24, 2005 (TW) 94137093

(51) Int. Cl. H01L 33/00

(52) U.S. Cl. 257/79

(57) ABSTRACT

A light emitting diode including a substrate, a semiconductor stacking layer, a first electrode and a second electrode is provided. The semiconductor stacking layer including an n-type doped semiconductor layer, a p-type doped semiconductor layer and an active layer is disposed on the substrate. The n-type doped semiconductor layer has In dopant. The active layer is disposed between the n-type doped semiconductor layer and the p-type doped semiconductor layer. In addition, the first electrode is disposed on the n-type doped semiconductor layer while the second electrode is disposed on the p-type doped semiconductor layer. In the light emitting diode mentioned above, no crack, open or pin hole are found in the n-type doped semiconductor layer, thus the light emitting diode mentioned above has lower power consumption, higher manufacturing yield and better reliability.

### CROSS-REFERENCE TO RELATED APPLICATION

This application claims the priority benefit of Taiwan application serial no. 94137093, filed on Oct. 24, 2005. All disclosure of the Taiwan application is incorporated herein by reference.

### BACKGROUND OF THE INVENTION

1. Field of Invention

The present invention relates to a semiconductor device. More particularly, the present invention relates to a light emitting diode (LED).

2. Description of Related Art

Light emitting diode is one of semiconductor devices and the material of its light emitting chip is mostly III-V group elements in semiconductor components, such as GaP, GaAs, and GaN. The principle of emitting light of light emitting diodes is converting electrical energy into light. That is, through applying electrical current to semiconductor components, electrons and holes are combined and the surplus energy is emitted in a way of light, so that an emission of light is formed. Other than by heating or discharging, the light of light emitting diodes belongs to a cold luminescence, so that the life of light emitting diodes can be longer than 100,000 hours and no idling time is needed. In addition, light emitting diodes have many advantages, such as fast response (about 10⁻⁹ second), small volume, less electricity expense, less pollution (no mercury), high reliability, adapted for mass production and so on, therefore, it can be used in extensive areas, for example, the light source of scanners requiring a fast response, the back light source or front light source of liquid crystal displays, the illumination of auto instrument panels, traffic lights, and general illuminating devices.

GaN is the main material of the conventional light emitting diodes and fabricated by an epitaxy method. Wherein, a light emitting diode mainly includes a substrate, an active layer, a p-type and an n-type doped semiconductor layers respectively disposed on the upside and downside of the active layer, and two external-connection electrodes. When a forward bias voltage is applied to the active layer by the external-connection electrodes, the current via the external-connection electrodes flows through the semiconductor layers. At this moment, electrons and holes inside the active layer are combined, causing the active layer to emit light.

In a usual light emitting diode, the n-type doped semiconductor layer usually has Si dopants in a high concentration. However, the Si dopants in high concentration make the n-type doped semiconductor layer likely to crack or break. When the n-type doped semiconductor layer cracks or breaks, it would be much difficult to fabricate electrodes on the n-type doped semiconductor layer. To be specific, if the n-type doped semiconductor layer cracks or breaks, the external-connection electrodes can not tightly contact the n-type doped semiconductor layer, causing the electrical characteristics of the light emitting diode worse, the operating voltage increased, the manufacturing yield decreased, and the cost relatively higher.

In addition, in an n-type doped semiconductor layer with Si dopant, pin holes are likely to occur, which make the light emitting diode produce a severe current leakage, and further decrease the reliability and poor ability of electrostatic resistance for the light emitting diode.

### SUMMARY OF THE INVENTION

Accordingly, the present invention is directed to provide a light emitting diode with high reliability and ability of electrostatic resistance.

For achieving the above or other objectives, the present invention provides a light emitting diode including a substrate, a semiconductor stacking layer, a first electrode and a second electrode. The semiconductor stacking layer including an n-type doped semiconductor layer, a p-type doped semiconductor layer, and an active layer is disposed on the substrate. The n-type doped semiconductor layer has In dopants. The active layer is disposed between the n-type doped semiconductor layer and the p-type doped semiconductor layer. In addition, the first electrode is disposed on the n-type doped semiconductor layer while the second electrode is disposed on the p-type doped semiconductor layer.

In an embodiment of the present invention, the material of the substrate includes sapphire, 6H—SiC, 4H—SiC, Si, ZnO, GaAs, MgAl₂O₄, or one of single crystal oxides whose lattice constant is close to nitride semiconductor.

In an embodiment of the present invention, the indium dopants are uniformly distributed in the n-type doped semiconductor layer.

In an embodiment of the present invention, the n-type doped semiconductor layer with the indium dopants further includes Si dopants.

In an embodiment of the present invention, the n-type doped semiconductor layer with the indium dopants further includes Si dopants and Mg dopants.

In an embodiment of the present invention, the material of the n-type doped semiconductor layer includes indium doped AlₓGa₁₋ₓN; 0≦x<1, In—Si doped AlₓGa₁₋ₓN; 0≦x<1, or In—Si—Mg doped AlₓGa₁₋ₓN; 0≦x<1.

In an embodiment of the present invention, the n-type doped semiconductor layer includes a plurality of local indium doped regions and a plurality of undoped regions, wherein the local indium doped regions and undoped regions are disposed alternately along the thickness direction of the n-type doped semiconductor layer.

In an embodiment of the present invention, the n-type doped semiconductor layer with indium dopants further includes Si dopants.

In an embodiment of the present invention, the n-type doped semiconductor layer with indium dopants further includes Si dopants and Mg dopants.

In an embodiment of the present invention, the material of the undoped regions includes GaN or AlGaN.

In an embodiment of the present invention, comparing with the material of nitride semiconductor of the local indium doped regions, the material of nitride semiconductor of the undoped regions has a larger band gap width.

In an embodiment of the present invention, the n-type doped semiconductor layer includes a buffer layer, a first contact layer, and a first cladding layer. Wherein, the buffer layer is disposed over the substrate; the first contact layer is disposed over the buffer layer; the first cladding layer is disposed over the first contact layer.

In an embodiment of the present invention, the n-type doped semiconductor layer further includes a nucleation layer disposed between the buffer layer and the first contact layer.

In an embodiment of the present invention, the p-type doped semiconductor layer includes a second cladding layer and a second contact layer. Wherein, the second cladding layer is disposed on the active layer while the second contact layer is disposed on the second cladding layer.

The n-type doped semiconductor layer of the light emitting diode of the present invent has In dopant, which can avoid the breaks and cracks of the conventional n-type doped semiconductor layer and make the n-type doped semiconductor layer and the electrodes contact each other tightly, so that the light emitting diode has high electrical conductivity and reliability.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a cross-sectional view of a light emitting diode of the first embodiment of the present invention.

FIG. 2 is a cross-sectional view of a light emitting diode of the second embodiment of the present invention.

FIG. 3 is a cross-sectional view of a light emitting diode of the third embodiment of the present invention.

FIG. 4 is a cross-sectional view of a light emitting diode of the fourth embodiment of the present invention.

FIG. 5 is a cross-sectional view of a light emitting diode of the fifth embodiment of the present invention.

FIG. 6 is a cross-sectional view of a light emitting diode of the sixth embodiment of the present invention.

### DESCRIPTION OF EMBODIMENTS

### The First Embodiment

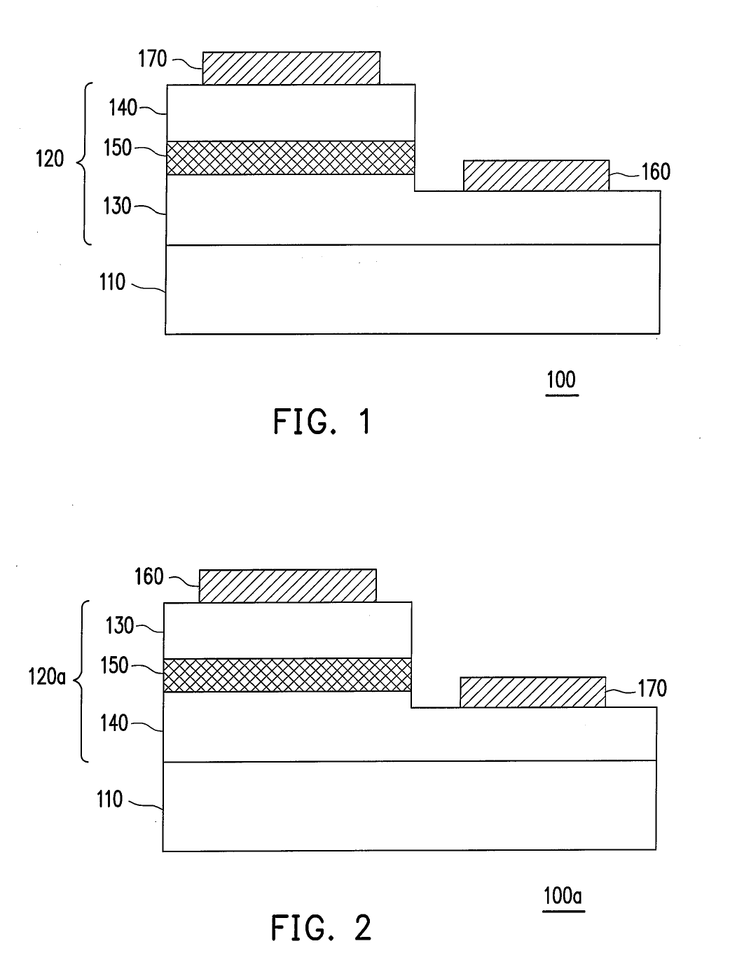

FIG. 1 is a cross-sectional view of a light emitting diode of the first embodiment of the present invention. Referring to FIG. 1, a light emitting diode 100 includes a substrate 100, a semiconductor stacking layer 120, a first electrode 160 and a second electrode 170. Wherein, the semiconductor stacking layer 120 including an n-type doped semiconductor layer 130, a p-type doped semiconductor layer 140 and an active layer 150 is disposed over the substrate 110. The n-type doped semiconductor layer 130 has In dopants. The active layer 150 is disposed between the n-type doped semiconductor layer 130 and the p-type doped semiconductor layer 140. In addition, the first electrode 160 is disposed over the n-type doped semiconductor layer 130 while the second electrode 170 is disposed over the p-type doped semiconductor layer 140.

To be specific, the material of the substrate 110 in the present embodiment is for example sapphire. In the other embodiments, the material of the substrate 110 can be 6H-SiC, 4H-SiC, Si, ZnO, GaAs, MgAl₂O₄, or one of single crystal oxides whose lattice constant is close to nitride semiconductor. Manufacturers can select a proper material of the substrate 110 according to requirements.

Following the above, in the semiconductor stacking layer 120 of the present embodiment, the n-type doped semiconductor layer 130, the active layer 150, and the p-type doped semiconductor layer 140 are stacked over the substrate 110 in sequence from down to up. Namely, the n-type doped semiconductor layer 130 in the semiconductor stacking layer 120 is disposed on the substrate 110. Especially, in the light emitting diode 100, the material of the n-type doped semiconductor layer is In doped AlₓGa₁₋ₓN with 0≦x<1. In dopants are uniformly distributed in the n-type doped semiconductor layer 130 and effectively improve the electrical characteristics of the light emitting diode 100. In more detail, the radius of an indium atom in the n-type doped semiconductor layer 130 is larger than the radius of a Ga atom, therefore, the In dopants in the n-type doped semiconductor layer 130 not only can overcome the dislocation of the n-type doped semiconductor layer 130 to avoid cracks and breaks of the conventional n-type doped semiconductor layer, but also can make the n-type doped semiconductor layer 130 have a smooth surface.

Known from FIG. 1 the active layer 150 is disposed on a portion of the n-type doped semiconductor layer 130, and a portion of the n-type doped semiconductor layer 130 is exposed; that is, the active layer 150 does not wholly cover the n-type doped semiconductor layer 130. Generally, the active layer 150 has a multiple quantum well structure, and the material of the active layer 150 is for example III-V group semiconductor components, such as the familiar material of GaP, GaAsP, AlGaAs, AlInGaP, or GaN.

Referring to FIG. 1 again, the p-type doped semiconductor layer 140 is disposed on the active layer 150, and the material of the p-type doped semiconductor layer 140 is for example Mg doped AlₓGa₁₋ₓN with 0≦x<1; or In, Si, Mg (main dopant) doped AlₓGa₁₋ₓN with 0≦x<1. In addition, the second electrode 170 is disposed on the p-type doped semiconductor layer 140 while the first electrode 160 is disposed on the exposed portion of the n-type doped semiconductor layer 130.

When a forward bias voltage is applied to the active layer 150 through the first electrode 160 and the second electrode 170, the current flows through the semiconductor stacking layer 120, and the electrons and holes inside the active layer 150 are combined, which makes the active layer 150 emits light.

Note that the n-type doped semiconductor layer 130 has In dopants, so the n-type doped semiconductor layer 130 has a smooth surface and is not easy to crack or break. On the other hand, because the n-type doped semiconductor layer 130 has a smooth surface, when the first electrode 160 is formed on the n-type doped semiconductor layer 130, the first electrode 160 can tightly contact the n-type doped semiconductor layer 130. As a result, the light emitting diode 100 has high electrical conductivity and production yield.

Following the above, for decreasing the operating voltage of the light emitting diode 100, Si dopants can be doped into the n-type doped semiconductor layer 130 with In dopants. Therefore, when a forward bias voltage is applied to the active layer 150 through the first electrode 160 and the second electrode 170, only a low operating voltage is needed for the light emitting diode 100 to emit light. In a preferred embodiment, besides the In dopants and the Si dopants, a little amount of Mg dopants can further be doped into the n-type doped semiconductor layer 130. Noting that, the n-type doped semiconductor layer 130 has less the Mg dopants than the Si dopants. The In—Si—Mg dopants in the n-type doped semiconductor layer 130 can decrease the ionization energy of electrons and holes and increase the mobility of carriers in the n-type doped semiconductor layer 130, so as to increase the probability of the combination of electrons and holes in the active layer 150.

To summary, the material of the n-type doped semiconductor layer of the light emitting diode of the present invention is the In doped AlₓGa₁₋ₓN with 0≦x<1. The In dopants can overcome the dislocation of the n-type doped semiconductor layer, so that the light emitting diode of the present invention has high electrical characteristics and production yield.

### The Second Embodiment

FIG. 2 is a cross-sectional view of a light emitting diode of the second embodiment of the present invention. In FIG. 1 and FIG. 2, the same or similar numerals indicate the same or similar elements whose functions and locations have been in detail described above, here they would not be repeated in description. As shown in FIG. 2, comparing with the first embodiment, in the semiconductor stacking layer 120a of the present embodiment, the p-type doped semiconductor layer 140, the active layer 150 and the n-type doped semiconductor layer 130 are stacked over the substrate 110 in a sequence from down to up.

Known from the aforementioned two embodiments that the light emitting diode of the present invention does not limit the disposed locations of the p-type doped semiconductor layer and the n-type doped semiconductor layer in the semiconductor stacking layer. The disposed locations of the p-type doped semiconductor layer and the n-type doped semiconductor layer can be exchanged while the active layer always need to be disposed between the p-type doped semiconductor layer and the n-type doped semiconductor layer.

For convenience, the following schematic views are illustrated according to the n-type doped semiconductor layer 130 being disposed on the substrate 110, and the same or similar labels indicate the same or similar elements which have been described above, so would not be repeated.

### The Third Embodiment

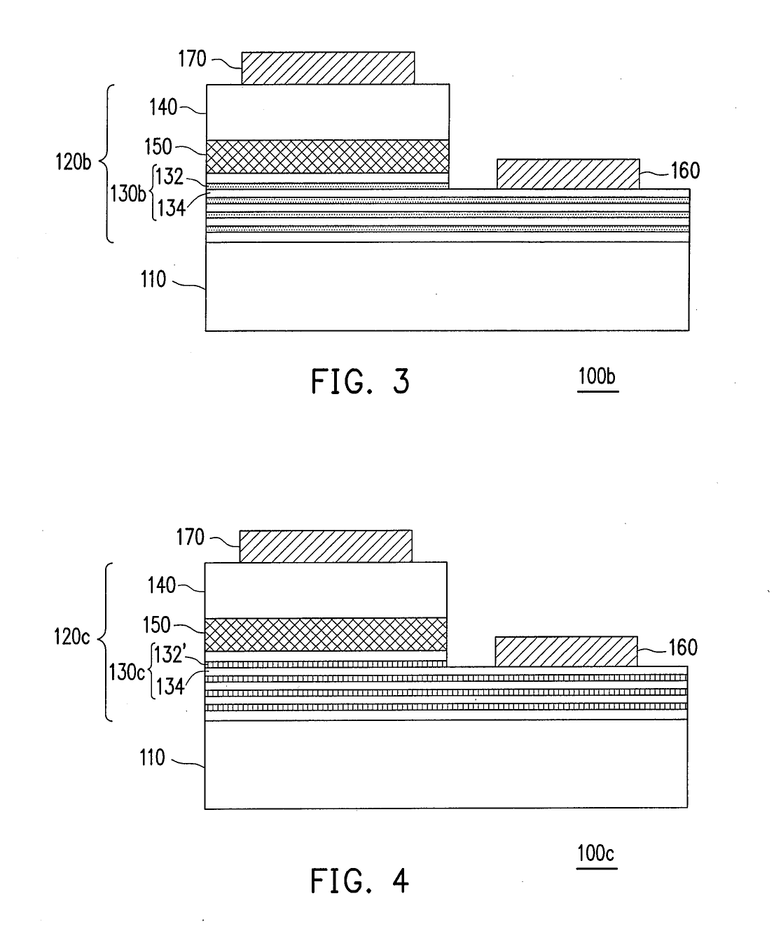

FIG. 3 is a cross-sectional view of a light emitting diode of the third embodiment of the present invention. Referring to FIG. 3, different from the first and second embodiments, for decreasing the operating voltage and the leakage current of the light emitting diode 100b, the n-type doped semiconductor layer 130b of the present embodiment includes a plurality of local In doped regions 132 and undoped regions 134, which are stacked alternately. Wherein, comparing with the material of nitride semiconductor of the local In doped regions 132, the material of nitride semiconductor of the undoped regions 134 has larger band gap width. For example, the material of the local In doped regions 132 of the present embodiment is the In doped AlₓGa₁₋ₓN with 0≦x<1, while the material of the undoped regions 134 is undoped GaN or undoped AlGaN. In the n-type doped semiconductor layer 130b, the quantity of both of the local In doped regions 132 and the undoped regions 134 is between 10 and 200. The spreading thickness of the local In doped regions 132 is for example between 10 and 200 nanometers while the spreading thickness of the undoped regions 134 is for example between 1 and 20 nanometers, and the thickness ratio of the local In doped regions 132 to the undoped regions 134 is about 10:1.

To be specific, the local In doped regions 132 and the undoped regions 134 are disposed alternately along the thickness direction of the n-type doped semiconductor layer 130b. When a forward bias voltage is applied to the active layer 150 through the first electrode 160 and the second electrode 170, the local In doped regions 132 and the undoped regions 134 disposed alternately can avoid the leakage current of the light emitting diode 100b and decrease the operating voltage of the light emitting diode 100b.

### The Fourth Embodiment

FIG. 4 is a cross-sectional view of a light emitting diode of the fourth embodiment of the present invention. Referring to FIG. 4, the present embodiment is similar to the third embodiment. Comparing with the third embodiment, the material of the local In doped regions 132′ of the light emitting diode 100c is In—Si doped AlₓGa₁₋ₓN with 0≦x<1. In the n-type doped semiconductor layer 130c, the quantity of both of the local In doped regions 132′ and the undoped regions 134 is between 10 and 200. The spreading thickness of the local In doped regions 132′ is for example between 10 and 200 nanometers while the spreading thickness of the undoped regions 134 is for example between 1 and 20 nanometers, and the thickness ratio of the local In doped regions 132′ to the undoped regions 134 is about 10:1.

### The Fifth Embodiment

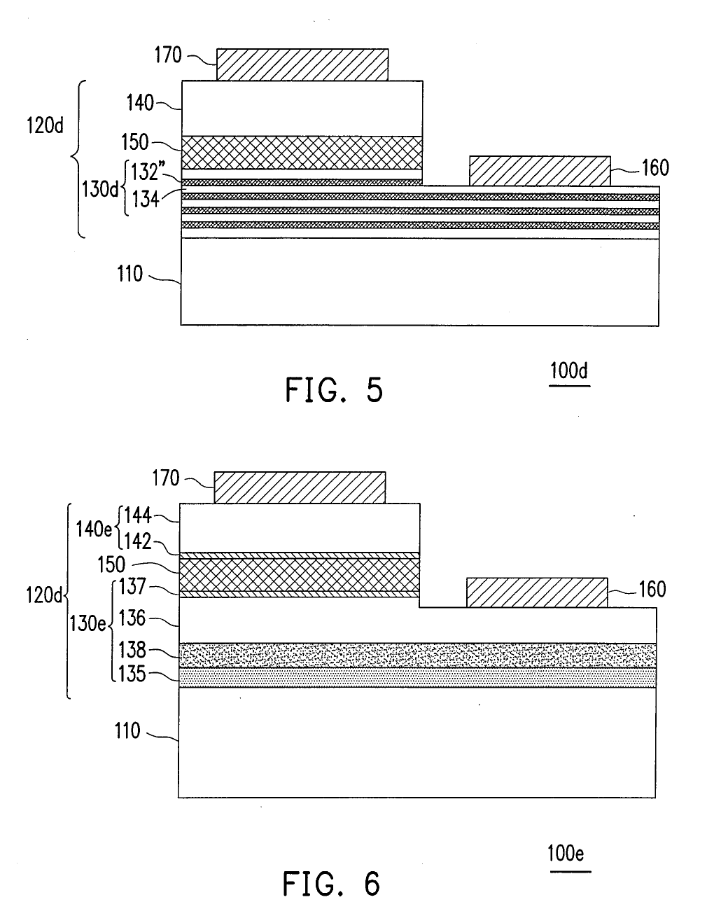

FIG. 5 is a cross-sectional view of a light emitting diode of the fifth embodiment of the present invention. The present embodiment is similar to the fourth embodiment. Comparing with the fourth embodiment, the material of the local In doped regions 132″ of the light emitting diode 100d is In—Si—Mg doped AlₓGa₁₋ₓN with 0≦x<1. In the n-type doped semiconductor layer 130d, the quantity of both of the local In doped regions 132″ and the undoped regions 134 is between 10 and 200. The spreading thickness of the local In doped regions 132″ is for example between 10 and 200 nanometers while the spreading thickness of the undoped regions 134 is for example between 1 and 20 nanometers, and the thickness ratio of the local In doped regions 132″ to the undoped regions 134 is about 10:1.

Remarkably, in the n-type doped semiconductor layer 130d, the quantity of Mg dopants is less than the quantity of Si dopants. The In dopants, the Si dopants and the Mg dopants in the n-type doped semiconductor layer 130 can decrease the ionization energy of electrons and holes and increase the mobility of carriers (electrons and holes) in the n-type doped semiconductor layer 130, so as to increase the probability of the combination of electrons and holes in the active layer 150.

### The Sixth Embodiment

FIG. 6 is a cross-sectional view of a light emitting diode of the sixth embodiment of the present invention. Referring to FIG. 6, in order that the light emitting diode has desired optical and electrical characteristics, buffer layers, nucleation layers and cladding layers, which have different functions, can further be disposed in the semiconductor stacking layer of the light emitting diode of the aforementioned embodiments.

In the present embodiment, the n-type doped semiconductor layer 130e includes a buffer layer 135 disposed over the substrate 110, a first contact layer 136 disposed over the buffer layer 135, and a first cladding layer 137 disposed over the first contact layer 136. The buffer layer 135 in the light emitting diode 100e can improve the quality of the epitaxy, so as to improve the optical and electrical characteristics of the light emitting diode 100e.

Following the above, the n-type doped semiconductor layer 130e further includes a nucleation layer 138 disposed between the buffer layer 135 and the first contact layer 136. The nucleation layer 138 can accelerate the epitaxy rate of the first contact layer 136, arrange the lattices in order, and make the first contact layer 136 have a smooth surface.

Knowing from FIG. 6, the first cladding layer 137 and the second cladding layer 142 are disposed over the upside and downside of the active layer 150. When a forward bias voltage is applied to the first electrode 160 and the second electrode 170 of the light emitting diode 110e, the first cladding layer 137 and the second cladding layer 142 can limit the carriers to the active layer 150 to increase the probability of the combination of electrons and holes in the active layer 150, so that the light emitting diode 110e has an improved light emitting efficiency.

Referring to FIG. 6 again, the p-type doped semiconductor layer 140e of the present embodiment includes a second cladding layer 142 and a second contact layer 144. Wherein, the second cladding layer 142 is disposed over the active layer 150 while the second contact layer 144 is disposed over the second cladding layer 142.

In summary, the light emitting diode of the present invention has at least the following advantages:

In the present invention, the In dopants, the In—Si doped dopants, or the In—Si—Mg doped dopants are doped into the n-type doped semiconductor layer, so that the structure strength and surface evenness of the n-type doped semiconductor layer can be improved, and the electrodes can be tightly connected with the n-type doped semiconductor layer. As a result, the light emitting diode 100 has high electrical conductivity and production yield.

In the present invention, a plurality of local In doped regions and undoped regions are disposed alternately along the thickness direction of the n-type doped semiconductor layer, so that the operating voltage of the light emitting diode can be decreased, the reliability of the light emitting diode can be increased, and the leakage current of the light emitting diode can be effectively reduced.

The present invention is disclosed above with its preferred embodiments. It is to be understood that the preferred embodiment of present invention is not to be taken in a limiting sense. It will be apparent to those skill in the art that various modifications and variations can be made to the structure of the present invention without departing from the scope or spirit of the invention. The protection scope of the present invention is in accordant with the scope of the following claims and their equivalents.

What is claimed is:

1. A light emitting diode, comprising:
a substrate;
a semiconductor stacking layer, disposed over the substrate, comprising:
an n-type doped semiconductor layer having In dopants;
a p-type doped semiconductor layer; and
an active layer, disposed between the n-type doped semiconductor layer and the p-type doped semiconductor layer;
a first electrode, disposed over the n-type doped semiconductor layer; and
a second electrode, disposed over the p-type doped semiconductor layer.

2. The light emitting diode as claimed in claim 1, wherein a material of the substrate comprises sapphire, 6H-SiC, 4H-SiC, Si, ZnO, GaAs, MgAl₂O₄, or one of single crystal oxides having a lattice constant close to a nitride semiconductor.

3. The light emitting diode as claimed in claim 1, wherein the In dopants are uniformly distributed in the n-type doped semiconductor layer.

4. The light emitting diode as claimed in claim 3, wherein the n-type doped semiconductor layer with the In dopants further comprises Si dopants.

5. The light emitting diode as claimed in claim 3, wherein the n-type doped semiconductor layer with the In dopants further comprises Si dopants and Mg dopants.

6. The light emitting diode as claimed in claim 1, wherein a material of the n-type doped semiconductor layer comprises In doped AlₓGa₁₋ₓN with 0≦x<1, In—Si codoped AlₓGa₁₋ₓN with 0≦x<1, or In—Si—Mg codoped AlₓGa₁₋ₓN with 0≦x<1.

7. The light emitting diode as claimed in claim 1, wherein the n-type doped semiconductor layer comprises:
a plurality of local In doped regions; and
a plurality of undoped regions, wherein the local In doped regions and the undoped regions are disposed alternately along a thickness direction of the n-type doped semiconductor layer.

8. The light emitting diode as claimed in claim 7, wherein the n-type doped semiconductor layer with the In dopants further comprises Si dopants.

9. The light emitting diode as claimed in claim 7, wherein the n-type doped semiconductor layer with the In dopants further comprises Si dopants and Mg dopants.

10. The light emitting diode as claimed in claim 7, wherein a material of the undoped regions comprises GaN or AlGaN.

11. The light emitting diode as claimed in claim 7, wherein a material of nitride semiconductor of the undoped regions, compared with a material of nitride semiconductor of the local In doped regions, has a larger band gap width.

12. The light emitting diode as claimed in claim 1, wherein the n-type doped semiconductor layer comprising:
a buffer layer, disposed on the substrate;
a first contact layer, disposed over the buffer layer; and
a first cladding layer, disposed over the first contact layer.

13. The light emitting diode as claimed in claim 12, wherein the n-type doped semiconductor layer further comprises a nucleation layer disposed between the buffer layer and the first contact layer.

14. The light emitting diode as claimed in claim 1, wherein the p-type doped semiconductor layer comprising:
a second cladding layer, disposed over the active layer; and
a second contact layer, disposed over the second cladding layer.
